(19) United States
(12) Patent Application Publication
(10) Pub. No.: US 2002/0072210 A1
(43) Pub. Date: Jun. 13, 2002

(54) Method for forming liner layer in sin spacer

(76) Inventors: Chi-Min Hsu, Taipei (TW); Wei-Wen Chen, Hsin-Chu City (TW)

Correspondence Address: LOWE HAUPTMAN GILMAN & BERNER , LLP, 1700 Diagonal Road, Suite 310, Alexandria, VA, 22314, US

(21) Appl. No.: 09/725,067

(22) Filed: Nov. 29, 2000

(51) Int. Cl. H01L 21/3205

(52) U.S. Cl. 438/595

(57) ABSTRACT

A method for forming a liner layer in silicon nitride spacers is disclosed. The method provides a semiconductor substrate having a polysilicon gate structure thereon. Then, as a key step of the present invention is forming a silicon oxynitride layer on the polysilicon gate structure and thereafter a silicon oxide layer is formed on the silicon oxynitride layer. Next, a conformal silicon nitride layer is formed on the semiconductor substrate and the silicon oxide layer. Moreover, on the sides of the silicon oxide layer, the spacers of silicon nitride are formed by anisotropically etching the silicon nitride layer.

### BACKGROUND OF THE INVENTION

1. Field of the Invention

The present invention generally relates to a method for forming a liner layer in silicon nitride spacer, and more particularly to a method for forming a silicon oxynitride layer as a liner layer for silicon nitride spacer.

2. Description of the Prior Art

As the design rule of semiconductor devices shrink continuously, improvements both in fabrication and structure of them are caused. For example, for spacers on the sidewall of gate electrode in a metal-oxide-semiconductor (MOS) transistor, conventional material of the spacers utilize silicon oxide, but silicon nitride spacers are used for the distinguishment from interlevel dielectric layer made from silicon oxide when semiconductor process makes progress to self-aligned contact (SAC) process.

FIG. 1 shows conventional silicon nitride spacers structure. A substrate 100 is provided, and a polygate electrode 120 and a gate oxide layer 110 are formed on the substrate 100. Silicon nitride spacers 130 are formed on the sidewalls of polygate electrode 120, and a silicon oxide layer 120 as a liner layer is formed between the substrate 100 and the silicon nitride spacer 130. A liner layer 112, formed before silicon nitride spacers, is used as a buffer layer because the adhesion between silicon nitride spacers and silicon is not well. There are two conventional methods for forming this liner layer 112, that one is chemical vapor deposition method, and the other is thermal growth oxidation method.

Conventional chemical vapor deposition methods use either mixture of silicomethand with oxygen or silicomethand with ammonia to form a silicon oxide layer on the surface of a wafer. However, it is not easy to form a very thin silicon oxide layer because the liner layer 112 formed by chemical vapor deposition method has poor step coverage and no compensation for the loss of the critical dimension of poly silicon gate.

The thermal oxidation method is to put the wafer into a furnace within oxygen therein and to heat up. The silicon oxide layer formed by thermal oxidation method possesses the best electrical and physical characteristics and it is the only one choice when the properties of silicon oxide are the most concerned. However, the thermal oxidation method causes the loss of the critical dimension, because oxygen will diffuse into polysilicon and react with silicon to form silicon dioxide in the re-oxidation process of polysilicon. As depicted in FIG. 1, dimension 120-1 is an original critical dimension of poly silicon gate, but the width is reduced as the dimension 120-2 of FIG. 1.

When re-oxidation of poly silicon is performed, oxygen will diffuse into both top and bottom sides of gate oxide layer such that both silicon substrate and polysilicon are consumed to form oxide layers thereafter. The bird's beak regions are therefore enlarged in the portion of gate oxide layer and cause the silicon substrate consumption in the source and drain extension regions. As depicted in FIG. 1, dimension 110-1 is an original thickness of the gate oxide layer 110. When the bird's peak regions at the sides of the gate oxide layer 110 are formed by performing re-oxidation, the thickness of dimension 110-2 is depicted in FIG. 1, and the silicon loss in the source and drain extension regions is depicted as dimension 112-1.

Moreover, an anisotropically etching is performed on the silicon nitride layer for forming spacers. The etching ratio of silicon nitride and silicon oxide is about 1.6 so that the over-etching range depicted as 112-2 of the liner layer 112 happens during forming spacers by etching silicon nitride.

### SUMMARY OF THE INVENTION

In accordance with the present invention, a straightforward method is provided for forming a thin silicon oxynitride layer with high quality and uniformity as a liner layer for silicon nitride spacers. In the present invention, the formation of the silicon oxynitride layer is performed by nitrogen plasma doping process or thermal furnace. The present invention simultaneously resolves the problems on the contraction of the critical dimension of poly silicon gate, enlargement of the bird's beak of gate oxide layer and doping depletion of the source and drain extension regions of all resulted from liner oxidation.

It is another object of this invention that the preferred liner layer can provide better control on the critical dimension of poly silicon. A silicon oxynitride layer is a better barrier layer for preventing silicon and poly silicon from consumption and diffusion of oxygen and water thereto, respectively. The thickness of poly silicon gate may be maintained to it's original thickness.

It is a further object of this invention to reduce the enlargement of the bird's peaks of the gate oxide layer. The silicon oxynitride layer can prevent oxygen from permeating into the top and bottom sides of the gate oxide layer. Moreover, a well homogenous thickness of channel gate oxidation can reduce variation of the threshold voltage.

It is still another object of this invention to simplify the steps in the manufacturing process. In the process of this invention, a mixture of SiON and SiO₂ is formed and provides a better buffer layer for the silicon oxynitride spacers.

It is yet another object of this invention to reduce silicon consumption of the source and drain extension regions and diffusion region. Because the height difference from the bottom-side of gate electrode to the top-side of the source and drain extension regions during the formation of silicon oxynitride layer is miniature, there can be more surface channels formed in transistors.

Accordingly, the present invention provides a method for forming a liner oxide layer in silicon nitride spacers. The method provides a semiconductor substrate having a polysilicon gate structure thereon. Then, as a key step of the present invention is to form a silicon oxynitride layer on the polysilicon gate structure and thereafter a silicon oxide layer is formed on the silicon oxynitride layer. Next, a conformal silicon nitride layer is formed on the semiconductor substrate and the silicon oxide layer. Moreover, on the sides of the silicon oxide layer, the spacers of silicon nitride are formed by anisotropy etching the silicon nitride layer. There are two methods for forming the silicon oxynitride layer in the present invention. One method is to form an nitrogen implant region on the polysilicon gate structure by a method of nitrogen plasma doping process and to heat the nitrogen implant region by oxygen and thereafter forming the silicon oxynitride layer and the silicon oxide simultaneously. Another method for forming the silicon oxynitride layer is to heat the polysilicon gate structure in environment of mixing nitric monoxide and oxygen.

### BRIEF DESCRIPTION OF THE DRAWINGS

The foregoing aspects and many of the attendant advantages of this invention will become more readily appreciated as the same becomes better understood by reference to the following detailed description, when taken in conjunction with the accompanying drawings, wherein:

FIG. 1 is a schematic representation of silicon nitride spacers' structure by using conventional, prior art techniques;

FIG. 2 is a flow chart showing the steps for forming silicon nitride spacers' structure in accordance with a method disclosed herein;

FIG. 3A to 3E are schematic representations of structures at various stages during the formulation of silicon nitride spacers' structure in accordance with a method disclosed; and

FIG. 4A to 4E are schematic representations of structures at various stages during the formulation of silicon nitride spacers' structure in accordance with another method disclosed.

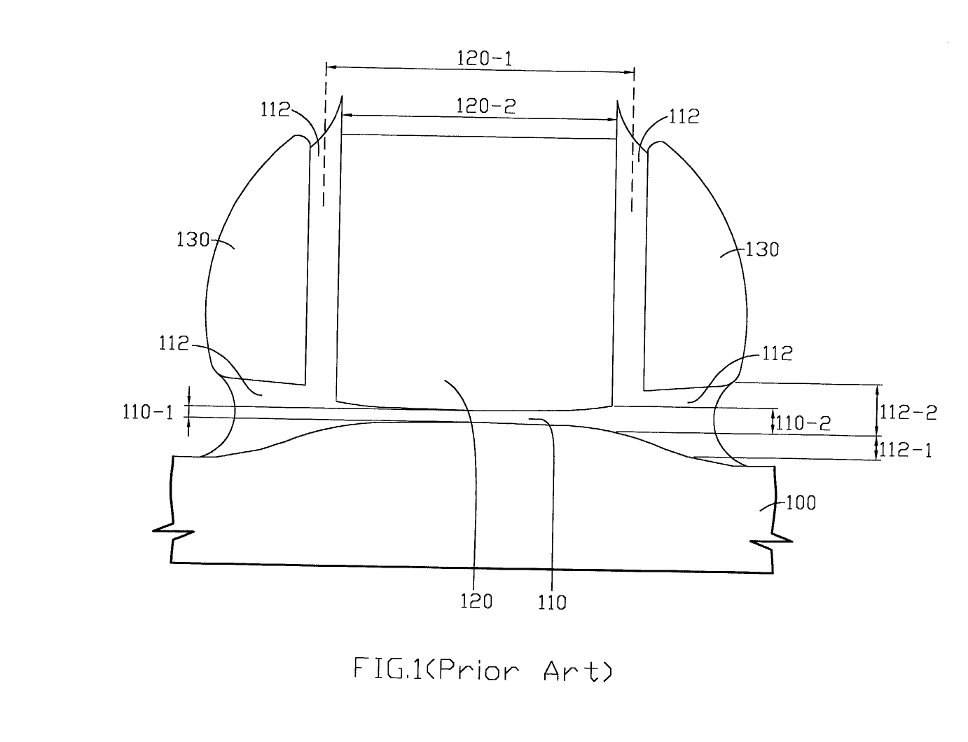

### DESCRIPTION OF THE PREFERRED EMBODIMENT

The semiconductor devices of the present invention are applicable to a broad range of semiconductor devices and can be fabricated from a variety of semiconductor materials. Thus, it is not intended that the semiconductor devices of the present invention be limited to the structure illustrated.

Further, although the embodiments illustrated herein are shown in two dimensional views with various regions having width and depth, it should be clearly understood that these regions are illustrations of only a portion of a single cell of a device, which may include a plurality of such cells arranged in a three-dimensional structure. Accordingly, these regions will have three dimensions, including length, width and depth, when fabricated in an actual device.

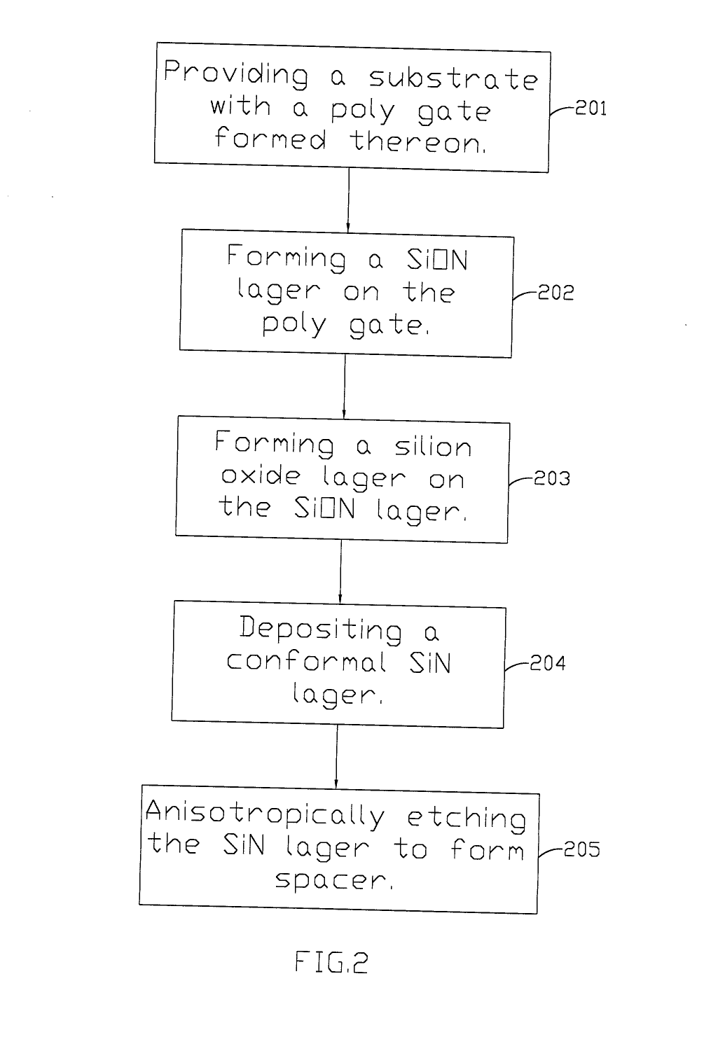

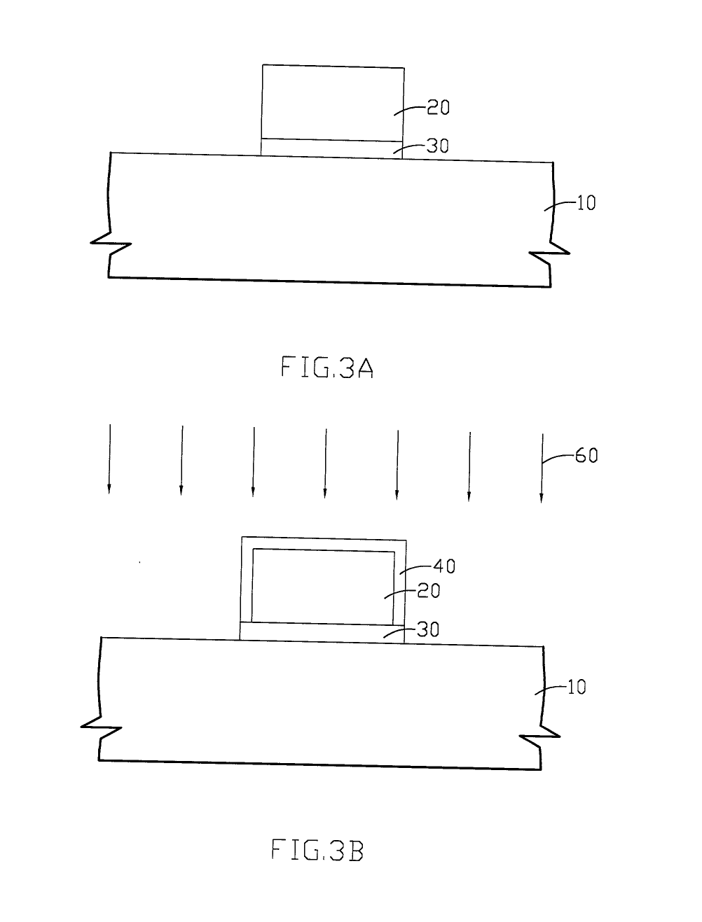

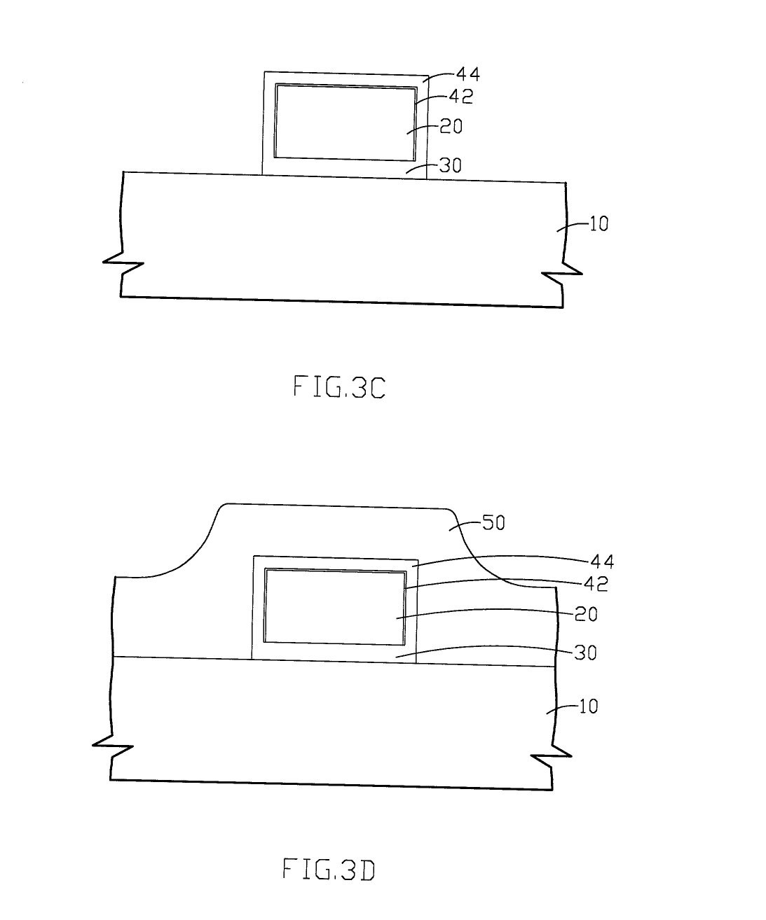

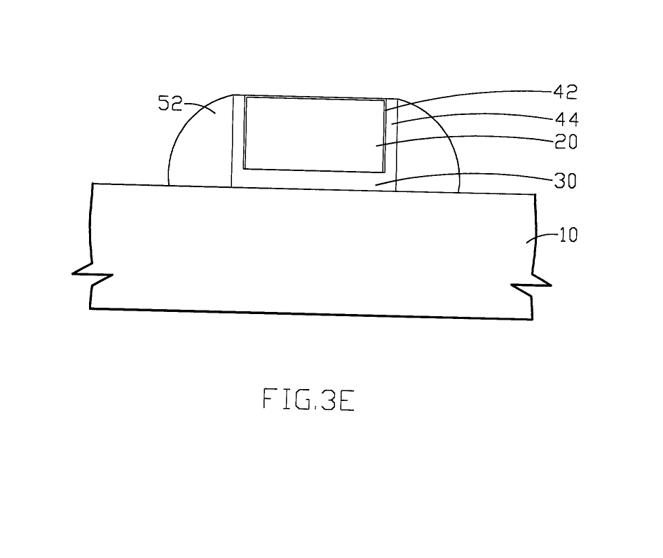

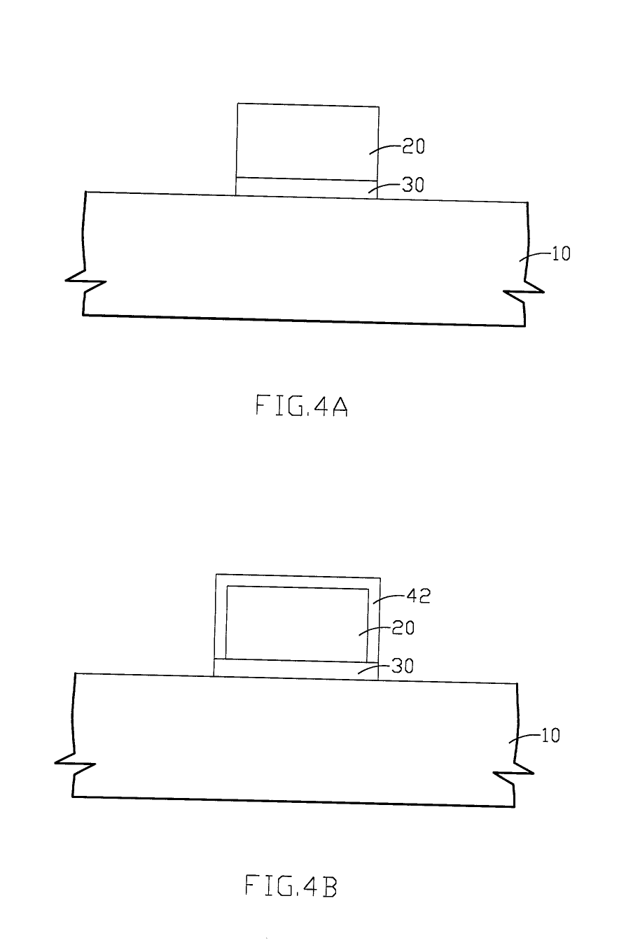

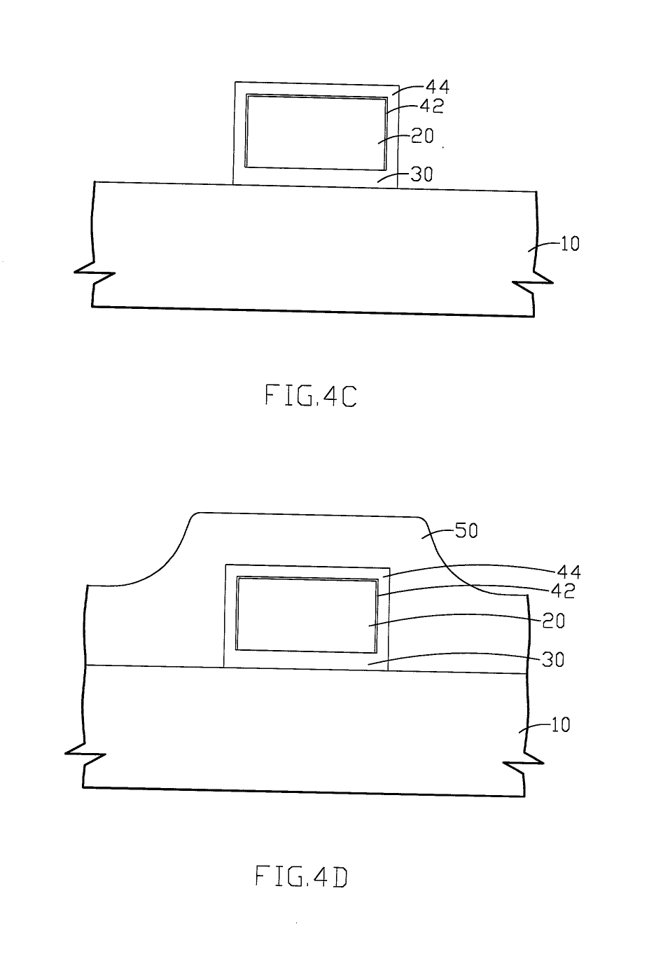

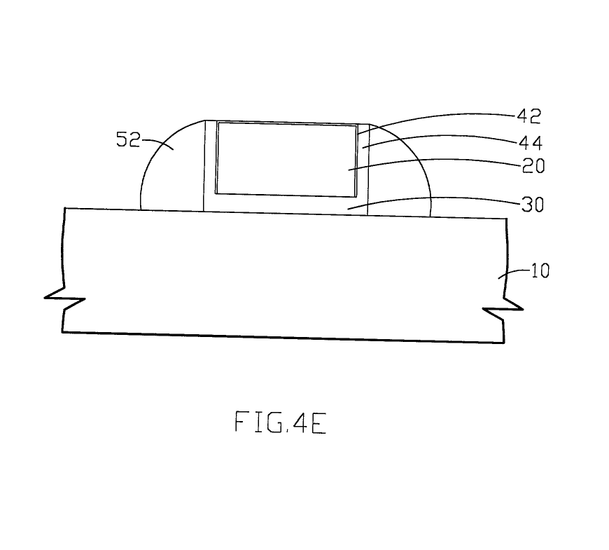

This invention substantially provides a method for forming a liner layer of silicon nitride spacers, and the flow chart of this invention is depicted in FIG. 2. First, a substrate is provided with a poly silicon gate structure formed thereon (step 201). Next, a silicon oxynitride layer is formed on the poly silicon gate (step 202) and a silicon oxide layer is formed thereon (step 203). To be specific, the step 202 and 203 are main steps of the present invention and they can be performed in sequence or in-situ for this invention. Next, a conformal silicon nitride layer is deposited (step 204). Then the silicon nitride spacers on the sidewalls of the silicon oxide layer are formed by anisotropically etching the silicon nitride layer (step 205). Accordingly, two preferred embodiments for forming silicon oxynitride layers are introduced, one is depicted from FIG. 3A to FIG. 3E and another is from FIG. 4A to FIG. 4E.

As shown in FIG. 3A, a gate oxide layer 30 is formed on a substrate 10 and a poly silicon gate 20 is then formed thereon by any conventional methods. The gate oxide layer 30 is grown on the substrate 10 by using conventional thermal oxidation method, and the poly silicon gate 20 is deposited on the silicon oxide layer 30 by using conventional chemical vapor deposition method (CVD). A gate patterned photoresist layer is then formed on the polysilicon layer by using conventional lithography process. The polysilicon layer 20 and silicon oxide layer 30 are sequentially etched using the photoresist layer as a mask by using conventional etching process.

Referring to FIG. 3B, a nitrogen implant layer 40 is formed on the surface of the poly silicon gate 20 by implanting nitrogen plasma 60. The ion implantation is to form the nitrogen implant layer 40 on the surface of the poly silicon gate 20 and growing a silicon oxynitride layer by thereafter heating process. This ion-implant step, that will generate a nitrogen-implant layer simultaneously, will not be shown in FIGS. The result is that a silicon oxynitride layer and a silicon oxide layer are formed on the surfaces of the substrate 10 and the poly silicon gate 20. To be specific, the silicon oxynitride layer and the silicon oxide layer on the surface of the substrate 10, prevents from the substrate 10 consumption resulting from not only the oxidation of the poly silicon gate 20, but also etching process before spaces formation. In the preferred embodiment, the ion implantation energy is between about 0.5 and 10 Kev and dose is between about 10¹⁰ to 10¹⁶ atoms/cm².

Next, as depicted in FIG. 3C, the wafer is placed into a furnace within oxygen at a temperature between about 600 to 1200° C. to grow a silicon oxynitride layer 42 and a silicon oxide layer 44 on the poly silicon gate 20 by using thermal oxidation method. In the preferred embodiment, the thin silicon oxynitride layer 42 has a thickness between about 5 to 100 Angstroms. The thickness of silicon oxide layer 44 is limited by the insulation of the silicon oxynitride layer 42.

Referring to FIG. 3D, a conformal silicon nitride layer 50 is deposited by using conventional low pressure chemical vapor deposition (LPCVD) method. In general low pressure chemical vapor deposition method, dichlorosilane (SiH₂Cl₂) is used as a main reactant for deposition of silicon nitride. A silicon nitride layer 50 is formed by the chemical reaction in a mixture of dichlorosilane and ammonia at a suitable temperature between about 700 toe 800° C. and the pressure is between about 0.1 to 1 Torr.

Next, as depicted in FIG. 3E, spacers 52 are formed by using conventionally anisotropically etching the silicon nitride layer 50.

Another preferred embodiment is then introduced by using another method forming silicon oxynitride layer. Referring to FIG. 4A, similarly, a gate oxide layer 30 is formed on a substrate 10 and a poly silicon gate 20 is then formed thereon by any conventional methods. The gate oxide layer 30 is grown on the substrate 10 by using conventional thermal oxidation method, and the poly silicon gate 20 is deposited on a silicon oxide layer by using conventional chemical vapor deposition method (CVD). A gate patterned photoresist layer is then formed on the polysilicon layer by using conventional lithography process. The polysilicon layer and silicon oxide layer are sequentially etched using the photoresist layer as a mask by using conventional etching process.

As a key step of this embodiment, in FIG. 4B, the wafer is placed into a furnace within nitric monoxide at a temperature between about 800 to 1200° C. to grow a silicon oxynitride layer 41. Next, as depicted in FIG. 4C, a silicon oxide layer 43 is formed on the silicon oxynitride layer 41 by using conventional thermal oxidation method. In this preferred embodiment, the thin silicon oxynitride layer 42 has a thickness between about 5 to 100 Angstroms. The thickness of silicon oxide layer 44 is limited by the insulation of the silicon oxynitride layer 42. A nitrogen implant layer is formed simultaneously on the substrate 10 by the ion implantation but not shown in this figure. The silicon oxynitride layer and the silicon oxide layer on the surface of the substrate 10, prevents from the substrate 10 consumption resulting from not only the oxidation of the poly silicon gate 20, but also etching process before spaces formation.

Referring to FIG. 4D, a conformal silicon nitride layer 50 is deposited by using conventional low pressure chemical vapor deposition (LPCVD). In general low pressure chemical vapor deposition, dichlorosilane (SiH₂Cl₂) is used as a main reactant for deposition of silicon nitride. A silicon nitride layer 50 is formed by the chemical reaction in a mixture of dichlorosilane and ammonia at a suitable temperature between about 700 toe 800° C. and the pressure is between about 0.1 to 1 Torr.

Next, as depicted in FIG. 4E, spacers 52 are formed by using conventionally anisotropically etching the silicon nitride layer 50.

Accordingly, the present invention is utilizing a thin silicon nitride layer as the barrier layer of the silicon nitride spacers. In the present invention, the silicon oxynitride layer is formed by using nitrogen plasma doping process or thermal furnace. The silicon oxynitride layer not only prevents from polysilicon consumption and diffusion of oxygen and water, but also limits oxygen penetrating into both top and bottom sides of the gate oxide layer. Therefore, the silicon oxynitride layer further prevents both the critical dimension of length of poly silicon gate from contraction and the bird's peak of the gate oxide layer from enlargement. Hence, the thickness of gate oxide of channel with a better uniformity can reduce the fluctuation the threshold voltage. Moreover, using silicon oxynitride layer as a liner layer in silicon nitride spacers can prevent source and drain extension regions from implant depletion resulting from liner oxidation. Furthermore, using silicon oxynitride layer as a liner of spacer of silicon nitride can reduce depletion of silicon in source and drain extension regions or diffusion.

Although specific embodiments have been illustrated and described, it will be obvious to those skilled in the art that various modifications may be made without departing from what is intended to be limited solely by the appended claims.

What is claimed is:

1. A method for forming a liner layer in silicon nitride spacers, said method comprising:
providing a semiconductor substrate with a polysilicon gate structure formed thereon;
forming a thin silicon oxynitride layer on said polysilicon gate structure; and
forming a silicon oxide layer on said silicon oxynitride layer.

2. The method according to claim 1, further comprising the following steps to form silicon nitride spacers:
forming a conformal silicon nitride layer on said semiconductor substrate and said silicon oxide layer; and
anisotropically etching said silicon nitride layer and thereafter forming said silicon nitride spacers on the sidewalls of said silicon oxide layer.

3. The method according to claim 2, wherein said silicon nitride layer is formed by chemical vapor deposition method.

4. The method according to claim 1, further comprising forming a silicon oxynitride layer and a silicon oxide layer on said semiconductor substrate.

5. The method according to claim 1, wherein said method of forming said silicon oxynitride layer comprises:
nitrogen implanting into said polysilicon gate structure to form a nitrogen-implant region; and
heating said nitrogen implant region by oxidation method and thereafter forming said silicon oxynitride layer.

6. The method according to claim 5, wherein said silicon oxide layer is formed with the step of heating said nitrogen implant region.

7. The method according to claim 5, wherein said step of heating is placing a wafer into a thermal furnace.

8. The method according to claim 1, wherein said method of forming said silicon oxynitride layer comprises forming said silicon oxynitride layer by heating said polysilicon gate structures in an environment of mixing nitric monoxide and oxygen.

9. The method according to claim 8, wherein said silicon oxide layer is formed with the step of heating said nitrogen implant region in the environment of mixing nitric monoxide and oxygen.

10. The method according to claim 8, wherein said step of heating is placing a wafer into a thermal furnace.

11. A method for forming a liner layer in silicon nitride spacers, said method comprising:
providing a semiconductor substrate having a polysilicon gate structure formed thereon;
nitrogen implanting into said polysilicon gate structure to form a nitrogen implantation region;
heating said nitrogen implantation region to form a thin silicon oxynitride layer; and
forming a silicon oxide layer on said silicon oxynitride layer.

12. The method according to claim 11, further comprising the following steps to form said silicon nitride spacers:
forming a conformal silicon nitride layer on said semiconductor substrate and said silicon oxide layer; and
anisotropically etching said silicon nitride layer and thereafter forming said silicon nitride spacers on the sidewalls of said silicon oxide layer.

13. The method according to claim 12, wherein said silicon nitride layer is formed by chemical vapor deposition method.

14. The method according to claim 11, further comprising a silicon oxynitride layer and a silicon oxide layer formed on said semiconductor substrate.

15. The method according to claim 11, wherein said silicon oxide layer is formed with said step of heating said nitrogen implant region by oxidation method.

16. The method according to claim 8, wherein said step of heating is placing a wafer into a thermal furnace.

17. A method for forming a liner layer in silicon nitride spacers, said method comprising:
providing a semiconductor substrate having a polysilicon gate structure formed thereon;
heating said substrate in an environment of mixing nitric monoxide and oxygen to form a silicon oxynitride layer on said gate structure; and
forming a silicon oxide layer on said silicon oxynitride layer.

18. The method according to claim 17, further comprising the following steps to form said silicon nitride spacers:
forming a conformal silicon nitride layer on said semiconductor substrate and said silicon oxide layer; and
anisotropically etching said silicon nitride layer and thereafter forming said silicon nitride spacers on the sidewalls of said silicon oxide layer.

19. The method according to claim 18, wherein said silicon nitride layer is formed by chemical vapor deposition method.

20. The method according to claim 17, further comprising a silicon oxynitride layer and a silicon oxide layer formed on said semiconductor substrate.

21. The method according to claim 17, wherein said silicon oxide layer is formed by heating said nitrogen implant region in the environment of mixing nitric monoxide and oxygen.

22. The method according to claim 17, wherein said step of heating is placing a wafer into a thermal furnace.

23. A method for forming silicon nitride spacers, said method comprising:
providing a semiconductor substrate having a polysilicon gate structure formed thereon;
forming a thin silicon oxynitride layer on said polysilicon gate structure;
forming a silicon oxide layer on said silicon oxynitride layer;
forming a conformal silicon nitride layer on said semiconductor substrate and said silicon oxide layer; and
anisotropically etching said silicon nitride layer and thereafter forming said spacers of silicon nitride on the sides of said silicon oxide layer.

24. The method according to claim 23, wherein said silicon nitride layer is formed by chemical vapor deposition method.

25. The method according to claim 23, further comprising a silicon oxynitride layer and a silicon oxide layer formed on said semiconductor substrate.

26. The method according to claim 23, where in said step of forming silicon oxynitride layer comprises:
nitrogen implanting into said gate structure to form a nitrogen implantation region; and
forming said silicon oxynitride layer by a step of heating said nitrogen implant region by oxidation.

27. The method according to claim 26, wherein said silicon oxide layer is formed with said step of heating said nitrogen implant region by oxidation.

28. The method according to claim 26, wherein said step of heating is placing a wafer into a thermal furnace.

29. The method according to claim 23, wherein said step of forming said silicon oxynitride layer comprises forming said silicon oxynitride layer by heating said polysilicon gate structure in the environment of mixing nitric monoxide and oxygen.

30. The method according to claim 29, wherein said silicon oxide layer is formed with said step of heating said nitrogen implant region in the environment of mixing nitric monoxide and oxygen.

31. The method according to claim 26, wherein said step of heating is placing a wafer into a thermal furnace.

32. A method for forming silicon nitride spacers, said method comprising:
providing a semiconductor substrate having a polysilicon gate structure formed thereon;
implanting nitrogen into said gate structure to form a nitrogen implantation region;
forming a thin silicon oxynitride layer by oxidizing said nitrogen implant region;
forming a conformal silicon nitride layer on said semiconductor substrate and said silicon oxide layer; and
anisotropically etching said silicon nitride layer and thereafter forming said spacers of silicon nitride on the sides of said silicon oxide layer.

33. The method according to claim 32, wherein said silicon nitride layer is formed by chemical vapor deposition method.

34. The method according to claim 32, further comprising a silicon oxynitride layer and a silicon oxide layer formed on said semiconductor substrate.

35. The method according to claim 32, wherein said silicon oxide layer is formed with said step of oxidizing said nitrogen implant region.

36. The method according to claim 32, wherein said step of oxidizing is placing a wafer into a thermal furnace with oxygen.

37. A method for forming silicon nitride spacers, said method comprising:
providing a semiconductor substrate having a polysilicon gate structure;
forming a silicon oxynitride layer by a step of heating said polysilicon gate in an environment of mixing nitric monoxide and oxygen;
forming a silicon oxide layer on said silicon oxynitride layer;
forming a conformal silicon nitride layer on said semiconductor substrate and said silicon oxide layer; and
anisotropically etching said silicon nitride layer and thereafter forming said spacers of silicon nitride on the sides of said silicon oxide layer.

38. The method according to claim 37, wherein said silicon nitride layer is formed by chemical vapor deposition method.

39. The method according to claim 32, further comprising a silicon oxynitride layer and a silicon oxide layer formed on said semiconductor substrate.

40. The method according to claim 37, wherein said silicon oxide layer is formed with said step of heating said nitrogen implant region in the environment of mixing nitric monoxide and oxygen.

41. The method according to claim 37, wherein said step of heating is placing a wafer into a thermal furnace.
